(19) United States
(12) Patent Application Publication
(10) Pub. No.: US 2023/0246470 A1
(43) Pub. Date: Aug. 3, 2023

(54) Battery Zero-Voltage Detection Methodologies and Applications Thereof

(71) Applicant: Google LLC, Mountain View, CA (US)

(72) Inventors: James Robert Lim, Mountain View, CA (US); David Wang, San Jose, CA (US); Haoxing Zhang, Campbell, CA (US); Shang Shi, Sunnyvale, CA (US)

(73) Assignee: Google LLC, Mountain View, CA (US)

(21) Appl. No.: 18/159,553

(22) Filed: Jan. 25, 2023

Related U.S. Application Data
(63) Continuation of application No. PCT/US2022/070446, filed on Jan. 31, 2022.

(51) Int. Cl. H02J 7/00; G01R 19/165; G01R 31/3835

(52) U.S. Cl. CPC H02J 7/007182; H02J 7/0029; G01R 19/16542; G01R 31/3835

(57) ABSTRACT

The present document describes battery zero-voltage (0V) detection methodologies and applications thereof. These techniques detect the occurrence of the 0V condition and enable the device to continue operation after one 0V condition. These techniques may, however, shut down the device after detecting a second occurrence of the 0V condition of the battery. In an aspect, a combination of hardware and software is used at a system side of a device, when the device is connected to an external power source, to detect a 0V condition and/or distinguish the 0V condition from an undervoltage-protection (UVP) condition.

### BACKGROUND

Lithium-ion (Li-ion) batteries are susceptible to degradation at lower voltages. Such degradation can be in the form of copper dissolution and/or gas formation. Because of this susceptibility to low-voltage degradation, many systems integrate Li-ion batteries with protection integrated circuit (PIC) chips, which can open metal-oxide-semiconductor field-effect transistors (MOSFETs) that prevent charge if the battery cell voltage drops to, e.g., less than one volt (V). A battery cell voltage of <1V is referred to as a zero-voltage (0V) condition. If the battery cell voltage decreases to <1V and the PIC chip has a “0V forbidden” flag enabled within the PIC chip, then a device powered by the battery becomes non-recoverable (e.g., “bricked”) by a user of the device.

During long-term storage (e.g., one year or more), Li-ion batteries may continue to self-discharge. Smaller battery cells (e.g., <1000 milliamps (mA)) have less capacity than larger battery cells and, in many cases, have a higher discharge rate than the larger battery cells. Because of this difference in capacity, smaller battery cells can experience a 0V condition during storage (e.g., storage after manufacture but prior to consumer use). Recent developments in battery-cell chemistries enable many Li-ion batteries to safely withstand one 0V condition and still be operational but, perhaps, not a second 0V condition. However, many PIC chips do not permit operation of the battery after the “0V forbidden” flag is enabled, thereby preventing further use of a battery that may still be usable.

### SUMMARY

The present document describes battery zero-voltage (0V) detection methodologies and applications thereof. These techniques detect the occurrence of the 0V condition and enable the device to continue operation after one 0V condition. These techniques may, however, shut down the device after detecting a second occurrence of the 0V condition of the battery. In an aspect, a combination of hardware and software is used at a system side of a device, when the device is connected to an external power source, to detect a 0V condition and/or distinguish the 0V condition from an undervoltage-protection (UVP) condition.

In aspects a method for managing charging events of a battery in an electronic device is disclosed. The method includes: measuring a battery voltage of the battery in response to a detection of an electrical connection to an external power source for initiating a charging sequence; detecting a zero-voltage condition based on the battery voltage being below a first threshold voltage; incrementing an integer counter by one count in response to the detection of the zero-voltage condition; comparing the integer counter to a second threshold; and charging the battery when the integer counter is below the second threshold effective to permit the battery to experience at least one occurrence of the zero-voltage condition. Here, incrementing the integer counter may include accessing a memory of the electronic device to increase the integer counter by one count, and the integer counter may represent a total number of occurrences of the zero-voltage condition for the battery over a life of the battery. Also, the method may further include determining that the total number of occurrences of the zero-voltage condition for the battery may be less than or equal to the second threshold. When the second threshold is one, the battery may experience the zero-voltage condition one time. The method may further comprise preventing the charging of the battery when the integer counter is greater than the second threshold. The method may comprise providing a return-merchandizing-authorization notification to a user of the electronic device. The providing of the return-merchandizing-authorization notification may include presenting a displayable notification via a display device of the electronic device. The providing of the return-merchandizing-authorization notification may include providing an audible message to the user. Also, the method may further comprise, subsequent to providing the return-merchandizing-authorization notification, shutting down the electronic device to prevent further use of the battery. Further, in response to the detection of the electrical connection to the external power source and prior to measuring the battery voltage, a delay might be caused to occur before initiating the charging sequence. Also, the measuring of the battery voltage may include using sensing circuitry that bypasses a power path to the battery to sense the battery voltage without driving current to the battery. In aspects, the incrementing of the integer counter by one count may include setting a bit in the memory of the electronic device to one. In some implementations, the method may further comprise using a comparator circuit to trigger the zero-voltage condition when the battery voltage of the battery drops below a trigger point of the comparator circuit, the trigger point set to one volt.

In further aspects, an electronic device is disclosed comprising: a battery; a default charger integrated circuit configured to cause a charging delay that delays battery charging when the electronic device is electrically connected to an external power source; and a comparator circuit powered by battery voltage of the battery. In aspects, the comparator circuit may have a trigger point that triggers when a battery voltage of the battery decreases to less than the trigger point. Also, the electronic device comprises a system having a processor and memory. The system may be configured to implement a battery-manager module configured to perform the method described above. The electronic device may further comprise cell-sense lines directed from the battery to the system and configured to bypass a field-effect transistor and a power path to the battery.

In some aspects, another method for detecting a zero-voltage condition of a battery in an electronic device is disclosed. The method includes pre-charging the battery using an electrical connection to an external power source, the battery having triggered an undervoltage-protection condition based on a battery voltage of the battery decreasing below a first threshold voltage. The method further includes generating an undervoltage-protection profile of the battery voltage during the pre-charging of the battery based on interactions between protection integrated circuits, the battery, and a system of the electronic device. Also, the method includes mapping the undervoltage-protection profile to create a signature pattern. In addition, the method includes using one or more characteristics of the signature pattern to distinguish between the undervoltage-protection condition of the battery and the zero-voltage condition of the battery, where the zero-voltage condition is defined by a second threshold voltage that is less than the first threshold voltage of the undervoltage-protection condition.

In aspects, an electronic device is disclosed. The electronic device includes a battery, sensing circuitry, and a system. The sensing circuitry has at least two protection integrated circuits each having a pair of field-effect transistors coupled with two body diodes to form a bidirectional power switch usable during a pre-charge of the battery to generate an undervoltage-protection profile for distinguishing between an undervoltage condition of the battery and a zero-voltage condition of the battery. The system has processor and memory and is configured to implement a battery-manager module configured to perform the method described above.

This summary is provided to introduce simplified concepts of battery zero-voltage detection methodologies and applications thereof, which are further described below in the Detailed Description. This summary is not intended to identify essential features of the claimed subject matter, nor is it intended for use in determining the scope of the claimed subject matter.

### BRIEF DESCRIPTION OF THE DRAWINGS

The details of one or more aspects of battery zero-voltage detection methodologies and applications thereof are described in this document with reference to the following drawings. The same numbers are used throughout the drawings to reference like features and components:

FIG. 1 illustrates an example implementation of an electronic device configured for battery zero-voltage detection methodologies and applications thereof in accordance with the techniques described herein;

FIG. 2 illustrates an example implementation of the electronic device from FIG. 1 in more detail;

FIG. 3 illustrates an example implementation of sensing circuitry having voltage-sensing lines usable to sense battery-cell voltage, in accordance with the techniques described herein;

FIG. 4 illustrates a plot representing an example undervoltage-protection (UVP) profile generated during a pre-charge of a battery that has triggered a UVP condition;

FIG. 5 depicts an example method for controlling battery charging of a battery in an electronic device; and

FIG. 6 depicts an example method for detecting a zero-voltage condition of a battery in an electronic device.

### DETAILED DESCRIPTION

The present document describes battery zero-voltage detection methodologies and applications thereof. The techniques described herein enable the system to detect occurrences of a 0V condition of the battery and enable continued operation of the device after at least one occurrence of the 0V condition.

In an example, consider a battery-powered device that has been sitting in a warehouse for over two years but has now been sold to a customer. When the customer plugs the device in to an external power source to charge the device's battery, the system of the device boots up and checks the battery voltage. If the battery has experienced a 0V condition (e.g., from self-discharge of battery voltage over the extended storage time), the system records a bit (or increments a counter) for this condition but still enables charging of the battery so the customer can use the device.

In another example, an electronic device using both line power and battery power may be experiencing a higher cell self-discharge than its typical rate (e.g., a fault situation). The system of the device, using the line power, can monitor the battery voltage to determine if a 0V condition has occurred more than once. Upon detection of, for example, a second occurrence of the 0V condition, the system can (i) notify a user to return the electronic device and (ii) shut down the device to prevent further battery usage.

In yet another example, an electronic device using both line power and battery power may be experiencing a higher cell self-discharge than its typical rate and may prompt the user to dismount the electronic device and charge the battery by connecting the electronic device to an external power source. During charging, the system checks the battery voltage and if the battery experienced a 0V condition, the system records a bit for this condition. The system then enables charging of the battery unless the system determines that the 0V condition has been triggered more than a threshold number of times (e.g., one, two).

In another example, consider a battery-powered device that is experiencing a higher cell self-discharge than its typical rate and triggers an undervoltage-protection (UVP) condition when the battery voltage decreases below a first threshold voltage (e.g., 2.3V, 2.5V, 2.8V, 3V), which shuts down the battery. Because the battery is shut down, the system may measure the battery voltage to have no voltage, even though the battery may still have some voltage (e.g., up to 3V). Therefore, it can be challenging to determine if the battery is in the safer UVP condition or if the battery voltage has decreased to the more-detrimental 0V condition. Upon charge, the system maps a UVP profile and indicates, based on the UVP profile, whether the battery has been in a 0V condition, which is defined by the battery voltage being less than a second threshold voltage (e.g., 0.5V, 0.75V, 1V, 1.25V, 1.5V).

Continuing, if the UVP profile indicates a 0V condition, the system records a bit or increments a stored value by one count. The system enables charging of the battery after one occurrence of the 0V condition (e.g., the bit or the stored value is equal to one). However, after a second occurrence of the 0V condition, the system notifies the user and shuts down the device. In some instances, the system may permit two or more occurrences of the 0V condition before shutting down the device, depending on the cell chemistry of the battery being able to withstand the 0V condition a second or more times.

The techniques described herein provide increased sustainability and longevity by enabling longer storage of devices (e.g., within warehouses and users' homes), which keeps devices in service longer before recycling or disposal. In addition, business flexibility is enhanced because the option of 0V detection via the system side (versus battery-pack side) provides better product return-on-investment (ROI) and yield.

While features and concepts of the described techniques for battery zero-voltage detection methodologies and applications thereof can be implemented in any number of different environments, aspects are described in the context of the following examples.

Example Device

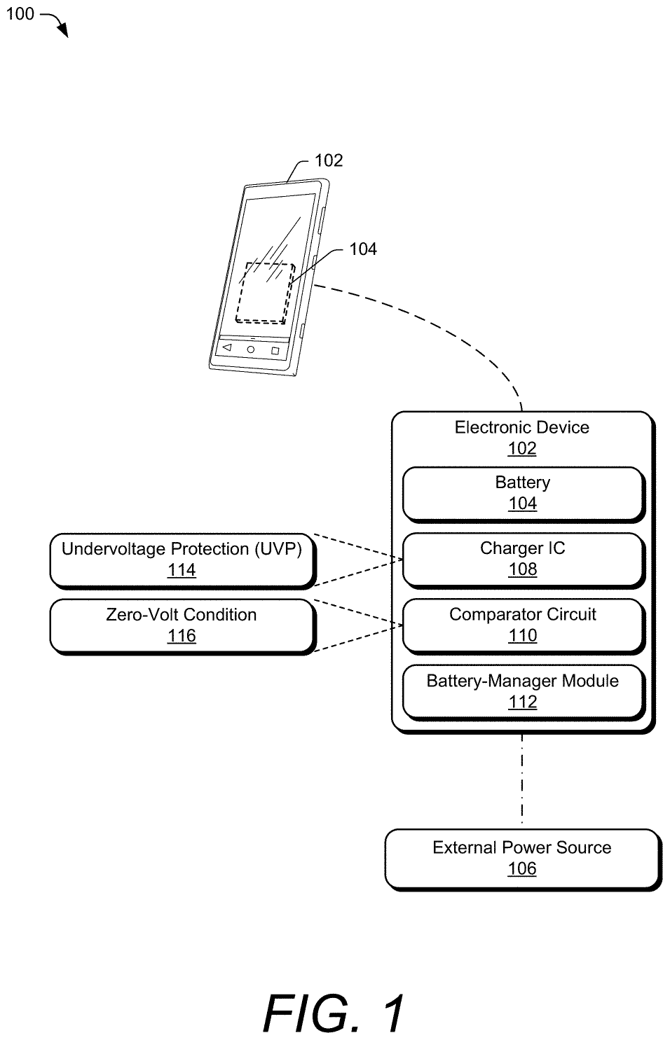

FIG. 1 illustrates an example implementation 100 of an electronic device configured for battery zero-voltage detection methodologies and applications thereof in accordance with the techniques described herein. The illustrated example includes an electronic device 102 having a battery 104, which provides battery power to the electronic device 102. In some aspects, the electronic device 102 may also be electrically connected to an external power source 106, which provides line power to the electronic device 102. In one example, the electronic device 102 can use the line power for some functions and use the battery power for one or more other functions. In this way, the battery-powered function can operate without interfering with a line-powered function. In some aspects, the coupling to the external power source 106 may be a wireless connection (e.g., using inductive coils).

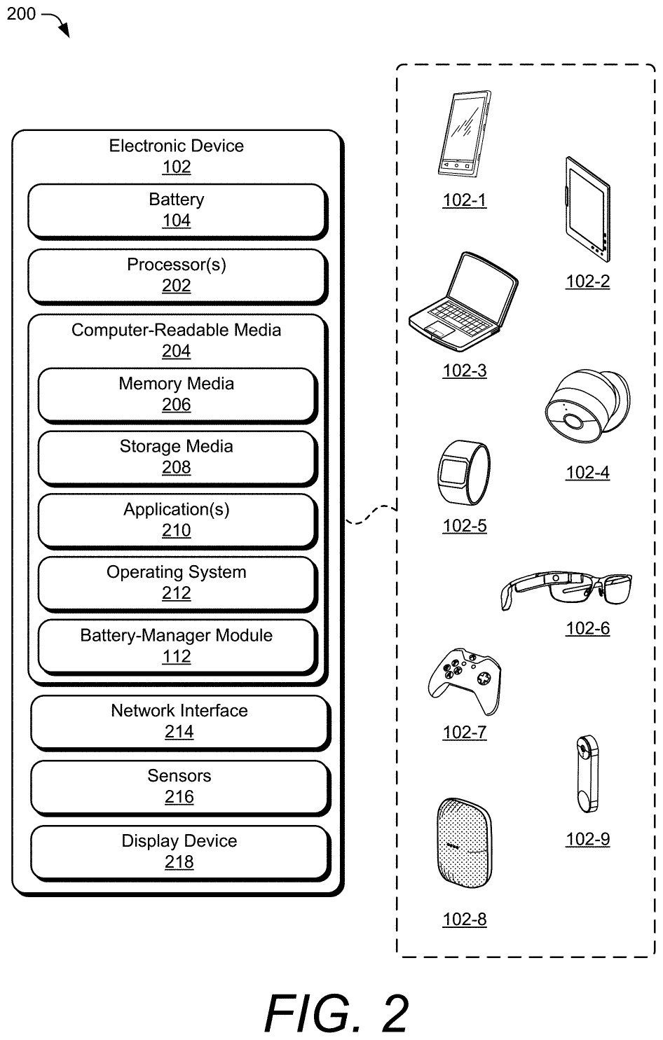

The battery 104 may be any suitable rechargeable battery. An example battery 104, as described herein (see FIG. 2), is a Li-ion battery. Any suitable Li-ion-battery chemistry may be implemented, several examples of which are described herein.

The electronic device 102 also includes a charger integrated circuit (IC) 108, a comparator circuit 110, and a battery-manager module 112. The charger IC 108 is configured to cause a delay between when an electrical connection to the external power source 106 is established and when charging of the battery 104 occurs. The charger IC 108 defaults to no charging and then checks battery voltage without disruption via system power.

The comparator circuit 110 is configured to be powered by battery voltage of the battery 104. In aspects, the comparator circuit 110 has a trigger point set to the first threshold voltage, e.g., approximately 1V. The comparator circuit 110 is triggered when the battery voltage drops below the trigger point.

The battery-manager module 112 is configured to monitor and manage the battery 104, including controlling charging events of the battery 104, monitoring battery state-of-charge (SOC), detecting 0V condition(s) of the battery, and enabling/disabling the battery 104 based on a number of times the battery 104 experiences the 0V condition over a life of the battery 104. The battery-manager module 112 is configured to check battery voltage (e.g., state-of-charge) and provide notifications (e.g., alerts) when detecting problems with the battery 104. In some aspects, the battery-manager module 112 can distinguish between a UVP condition 114 and a 0V condition 116 (even when the battery 104 is disabled) to determine whether the battery 104 has experienced a 0V condition 116 and/or exceeded its limit of occurrences of the 0V condition 116. The UVP condition 114 is defined as the battery voltage being less than a first threshold voltage (e.g., 2.3V, 2.5V, 2.8V, 3V). The 0V condition 116 is defined as a battery voltage being less than a second threshold voltage (e.g., 0.5V, 0.7V, 1V, 1.3V, 1.5V), which is less than the first threshold voltage of the UVP condition 114. By controlling charging events and enabling at least one occurrence of the 0V condition 116 of the battery 104, the battery-manager module 112 can extend the life of the battery 104 and therefore the usefulness of the electronic device 102.

The electronic device 102 may also be configured to communicate with one or more devices or servers over a network. By way of example and not limitation, the electronic device 102 may communicate data over a local-area-network (LAN), a wireless local-area-network (WLAN), a personal-area-network (PAN), a wide-area-network (WAN), an intranet, the Internet, a peer-to-peer network, point-to-point network, or a mesh network.

Consider now FIG. 2, which illustrates an example implementation of the electronic device from FIG. 1 in more detail. The electronic device 102 of FIG. 2 is illustrated with a variety of example devices, including a smartphone 102-1, a tablet 102-2, a laptop 102-3, a security camera 102-4, a computing watch 102-5, computing spectacles 102-6, a gaming system 102-7, a video-recording doorbell 102-8, and a speaker 102-9. The electronic device 102 can also include other devices, e.g., televisions, entertainment systems, desktop computers, audio systems, projectors, automobiles, drones, track pads, drawing pads, netbooks, e-readers, home security systems, and other home appliances. Note that the electronic device 102 can be mobile, wearable, non-wearable but mobile, or relatively immobile (e.g., desktops and appliances).

The electronic device 102 includes a battery (e.g., the battery 104). The battery 104 may be any suitable rechargeable battery. As described herein, the battery 104 may be a Li-ion battery. Various different Li-ion-battery chemistries may be implemented, some examples of which include lithium cobalt oxide (LiCoO₂), lithium iron phosphate (LiFePO₄), lithium manganese oxide (LiMn₂O₄ spinel, or Li₂MnO₃-based lithium-rich layered materials, LMR-NMC), and lithium nickel manganese cobalt oxide (LiNiMnCoO₂, Li-NMC, LNMC, NMC, or NCM and the various ranges of Co stoichiometry). Also, Li-ion batteries may include various different anode materials, including graphite based anodes, silicon (Si), graphene, and other cation intercalation/insertion/alloying anode materials.

The electronic device 102 includes one or more processors 202 (e.g., any of microprocessors, controllers, or other controllers) that can process various computer-executable instructions to control the operation of the electronic device 102 and to enable techniques for battery zero-voltage detection methodologies and applications thereof. Alternatively or additionally, the processor(s) 202 can be implemented with any one or combination of hardware elements, firmware, or fixed logic circuitry that is implemented in connection with processing and control circuits. Although not shown, the electronic device 102 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

The electronic device 102 also includes computer-readable media 204 (CRM 204). The CRM 204 includes memory media 206 and storage media 208. The CRM 204 may include one or more memory devices (e.g., the storage media 208) that enable persistent and/or non-transitory data storage (in contrast to mere signal transmission), examples of which include random access memory (RAM), non-volatile memory (e.g., any one or more of a read-only memory (ROM), flash memory, EPROM, EEPROM, etc.), and a disk storage device. A disk storage device may be implemented as any type of magnetic or optical storage device, such as a hard disk drive, a recordable and/or rewritable compact disc (CD), any type of a digital versatile disc (DVD).

Applications 210 and/or an operating system 212 implemented as computer-readable instructions on the computer-readable media 204 (e.g., the storage media 208) can be executed by the processor(s) 202 to provide some or all of the functionalities described herein. The computer-readable media 204 provides data storage mechanisms to store various device applications 210, an operating system 212, memory/storage, and other types of information and/or data related to operational aspects of the electronic device 102. For example, the operating system 212 can be maintained as a computer application within the computer-readable media 204 and executed by the processor(s) 202 to provide some or all of the functionalities described herein. The device applications 210 may include a device manager, such as any form of a control application, software application, or signal-processing and control modules. The device applications 210 may also include system components, engines, or managers to implement techniques for battery zero-voltage detection methodologies and applications thereof, such as the battery-manager module 112. The electronic device 102 may also include, or have access to, one or more machine learning systems.

Various implementations of the battery-manager module 112 can include, or communicate with, a System-on-Chip (SoC), one or more Integrated Circuits (ICs), a processor with embedded processor instructions or configured to access processor instructions stored in memory, hardware with embedded firmware, a printed circuit board with various hardware components, or any combination thereof.

The electronic device 102 may also include a network interface 214. The electronic device 102 can use the network interface 214 for communicating data over wired, wireless, or optical networks. By way of example and not limitation, the network interface 214 may communicate data over a local-area-network (LAN), a wireless local-area-network (WLAN), a personal-area-network (PAN), a wide-area-network (WAN), an intranet, the Internet, a peer-to-peer network, point-to-point network, or a mesh network. The network interface 214 can be implemented as one or more of a serial and/or parallel interface, a wireless interface, any type of network interface, a modem, or any other type of communication interface. Using the network interface 214, the electronic device 102 may communicate via a cloud computing service to access a platform having resources.

The electronic device 102 also includes one or more sensors 216, which can include any of a variety of sensors, including an audio sensor (e.g., a microphone), a touch-input sensor (e.g., a touchscreen, a fingerprint sensor, a capacitive touch sensor), an image-capture device (e.g., a camera or video camera), a proximity sensor (e.g., capacitive sensor), a motion-detection sensor (e.g., passive infrared sensor), a temperature sensor (e.g., thermistor), or an ambient light sensor (e.g., photodetector). The one or more sensors 216 may also include the charger IC 108 and/or the comparator circuit 110 shown in FIG. 1.

The electronic device 102 can also include a display device (e.g., display device 218). The display device 218 can include any suitable touch-sensitive display device, e.g., a touchscreen, a liquid crystal display (LCD), thin film transistor (TFT) LCD, an in-place switching (IPS) LCD, a capacitive touchscreen display, an organic light-emitting diode (OLED) display, an active-matrix organic light-emitting diode (AMOLED) display, super AMOLED display, and so forth. The display device 218 may be referred to as a display or a screen, such that digital content may be displayed on-screen.

Although not shown, the electronic device 102 also includes I/O interfaces for receiving and providing data. For example, the I/O interfaces may include one or more of a touch-sensitive input, a capacitive button, a microphone, a keyboard, a mouse, an accelerometer, a display, a light-emitting diode (LED) indicator, a speaker, or a haptic feedback device.

These and other capabilities and configurations, as well as ways in which entities of FIGS. 1 and 2 act and interact, are set forth in greater detail below. These entities may be further divided, combined, and so on. The implementation 100 of FIG. 1 and the detailed illustrations of FIG. 2 through FIG. 6 illustrate some of many possible environments, devices, and methods capable of employing the described techniques, whether individually or in combination with one another.

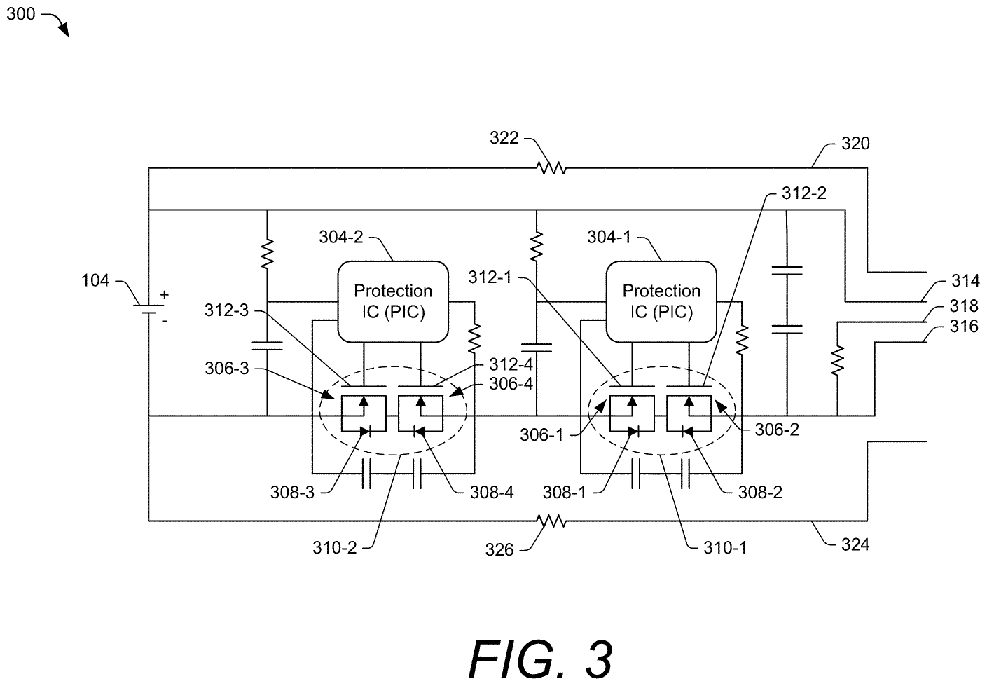

FIG. 3 illustrates an example implementation of sensing circuitry 300 having voltage-sensing lines usable to sense battery-cell voltage, in accordance with the techniques described herein. In particular, the sensing circuitry 300 is arranged to enable the system to bypass field-effect transistors (FETs) (e.g., MOSFETs) and a power path to the battery 104, which enables detection of the cell voltage without using or causing current flow. In the illustrated example, the sensing circuitry 300 is connected to a cell (e.g., the battery 104). The sensing circuitry 300 includes two protection ICs 304 (e.g., PIC 304-1, PIC 304-2) each with a pair of FETs 306 (e.g., MOSFETs). In the illustrated example, the circuitry 300 includes a first FET 306-1 paired with a second FET 306-2. The circuitry 300 also includes a third FET 306-3 paired with a fourth FET 306-4. Each pair of FETs 306 in FIG. 3 is arranged with two body diodes 308 that are back to back, forming a back-to-back connected dual-channel MOSFET, which creates a bidirectional power switch 310 (e.g., first and second bidirectional power switches 310-1 and 310-2). As illustrated, the body diodes 308 include body diodes 308-1 and 308-2 in the first bidirectional power switch 310-1 and body diodes 308-3 and 308-4 in the second bidirectional power switch 310-2. Further, each power switch 310 includes two gates 312 (e.g., a first gate 312-1 and a second gate 312-2 in the first power switch 310-1, a third gate 312-3 and a fourth gate 312-4 in the second power switch 310-2). The first gate 312-1 (and the third gate 312-3) may be a discharge field-effect transistor (discharge FET) and the second gate 312-2 (and the fourth gate 312-4) may be a charge FET. Further, because the two protection ICs 304 are in series, there are two body diodes that are also in series. For example, body diodes 308-2 and 308-4 are in series and body diodes 308-1 and 308-3 are in series.

When the battery voltage triggers a UVP condition by decreasing below the first threshold voltage (e.g., 2V, 2.3V, 2.5V, 2.8V, 3V), the first PIC 304-1 activates. For example, the first gate 312-1 opens (e.g., turns off) and blocks passage of electron current through its corresponding FET 306 (e.g., the first FET 306-1). However, the second gate 312-2 may still be closed (e.g., turned on), thereby enabling charging of the battery through the second FET 306-2 and the body diode 308-1. In some implementations, the second PIC 304-2 may similarly activate. For example, the third gate 312-3 opens (e.g., turns off) and blocks passage of electron current through its corresponding FET 306 (e.g., the third FET 306-3) based on the decreased battery voltage, but the fourth gate 312-4 remains closed (e.g., turned on) to enable charging of the battery through the fourth FET 306-4 and the body diode 308-3. Accordingly, when the battery voltage has triggered the UVP condition 114 (e.g., the battery voltage has dropped to below the trigger point), the battery 104 may be charged through the second gate 312-2 and the body diode 308-1 and, in some implementations, also through the fourth gate 312-4 and the body diode 308-3. In aspects, the first PIC 304-1 activates prior to the second PIC 304-2. Alternatively, the second PIC 304-2 may activate prior to the first PIC 304-1. The latency between activation of each of the first and second PICs 304-1 and 304-2, respectively, may be on the order of milliseconds (ms) or on the order of seconds (s).

The sensing circuitry 300 includes a positive-power line 314 and a negative-power line 316 connected to positive and negative cell voltages, respectively. The sensing circuitry 300 may also include a temperature-sensing line 318 configured to enable measurement of a temperature of the battery 104. In aspects, the temperature-sensing line 318 is directly connected to a negative temperature coefficient (NTC) thermistor or equivalent variable thermistor of the battery 104 to measure the temperature of the battery 104.

The sensing circuitry 300 also includes a first cell-sense line 320 that has a first high resistor 322 in-line and directly connects to positive cell voltage of the battery 104. In addition, the sensing circuitry 300 includes a second cell-sense line 324 that has a second high resistor 326 in-line and directly connects to negative cell voltage of the battery 104. The cell-sense lines 320 and 324 enable the battery voltage of the battery 104 to be sensed without running significant current to the battery 104 and with the high resistors 322 and 326 configured to protect against a short circuit. In addition, electrostatic discharge (ESD) components (not shown) may be included to protect against an electrical short. The cell-sense lines 320 and 324 also enable a more-accurate reading of the battery voltage by bypassing a voltage drop from V=IR (e.g., voltage V equals current I multiplied by resistance R). For instance, the sense lines 320 and 324 have high resistance (e.g., higher than the power path) but little to no current, which results in the battery voltage being equal to actual cell voltage less the IR of the power path (or sense path). In this case, the battery voltage is close to the actual cell voltage. In contrast, along the power path where large currents are used in both charge and discharge, any resistance in the power path (particularly for large currents, e.g., >1 ampere (A) multiplied by even a small resistance e.g., 100 milliohms (mΩ)) can lead to a significant battery voltage drop, such as 0.1V drop (1 A×100 mΩ) in the measurement of the battery voltage versus the actual cell voltage.

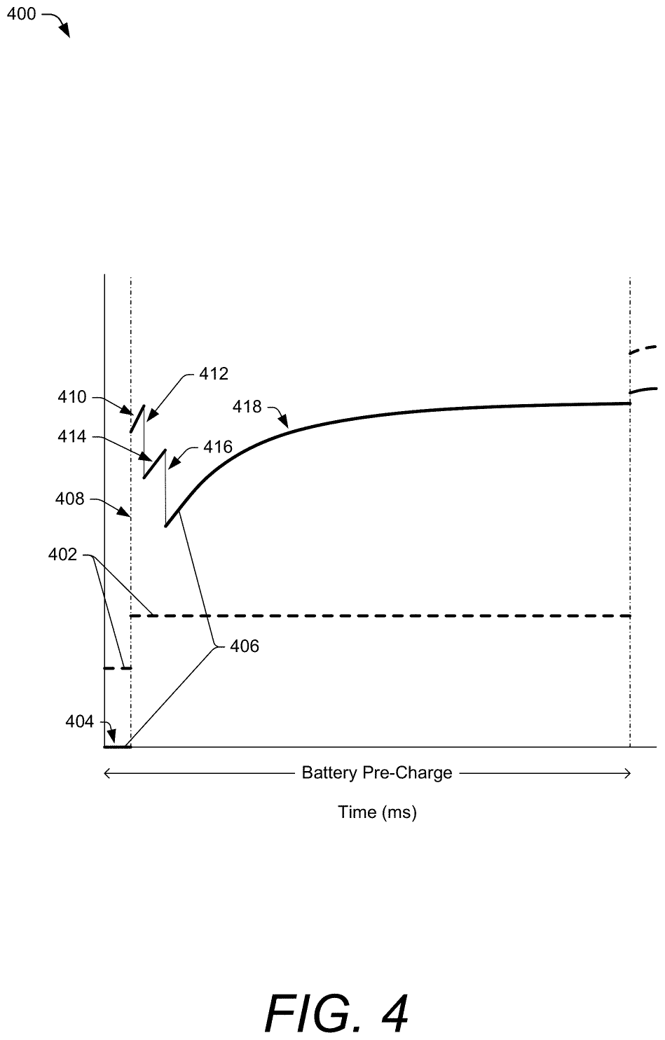

When the battery 104 is at zero or near-zero voltage, the addition of a low current to charge the battery 104 causes a quick rise (e.g., jump) in battery system voltage. As the cell voltage rises, to each PIC 304 UVP setting, each FET 306 closes, which then aligns the battery voltage with the battery system voltage (with the voltage add due to IR). For example, after the voltage jumps, one FET 306 closes and later another FET 306 closes, and then the battery voltage begins to equilibrate to begin a more “standard” path. A “standard” path is indicative of the battery system voltage being substantially equal to the actual battery voltage, due to the high resistance/voltage path through the body diodes being now through a more-ideal conduction path of the closed FETs 306 (e.g., high conduction path). An example of such a FET interaction is illustrated in FIG. 4.

FIG. 4 illustrates a plot 400 representing an example UVP profile generated during a pre-charge of a battery that has triggered a UVP condition. When a low current 402 (e.g., pre-charge) is applied to a battery that is at or near zero voltage (e.g., portion 404), a UVP profile 406 is generated that represents a change in the battery voltage of the battery with respect to time. Typically, a battery that is at or near zero voltage experiences a rise in the battery voltage as the battery 104 charges. Using the circuitry 300 in FIG. 3, application of the low current 402 causes a quick rise in the battery voltage (e.g., at 408 and portion 410) until one FET 306 closes, quickly dropping the voltage (e.g., at 412), followed by another rise (e.g., portion 414) in the voltage until another FET 306 closes, quickly dropping the voltage again (e.g., at 416). Then, the circuitry equilibrates and the voltage begins a more “standard” path (e.g., portion 418) of voltage increase during the pre-charge of the battery 104.

The behavior near the beginning of the UVP profile (voltage curve) may provide an indication as to whether the battery 104 was (just prior to the pre-charge) experiencing a UVP condition (e.g., between ˜1V and ˜3V, including 2V, 2.3V, 2.5V, and 2.8V) or the more-detrimental 0V condition (e.g., <0.5V, <0.75V, <1V, <1.25V, <1.5V). For example, this FET interaction near the beginning of the UVP profile occurs significantly quicker for the UVP condition than it does for the 0V condition because, in comparison to the UVP condition, the battery 104 is at a deeper voltage in the 0V condition (e.g., <1.5V, <1.25V, <1V, <0.75V, <0.5V) and the FETs take more time to close.

Accordingly, if the FET interaction near the beginning of the UVP profile occurs very quickly (e.g., on the order of milliseconds, including <10 ms, <20 ms, <30 ms, <40 ms, <50 ms), then it is likely that the battery 104 was in the UVP condition. In contrast, if the FET interaction near the beginning of the UVP profile occurs more slowly (e.g., on the order of seconds, including between 1 second and 10 seconds, between 5 and 20 seconds), then it is likely that the battery 104 was in the 0V condition. Thus, the closing of the FETs 306 is observed and used to indicate the timing of how deep in low voltage the battery cells were prior to applying the pre-charge, and the timing is used to differentiate between the UVP condition and the 0V condition.

Example Methods

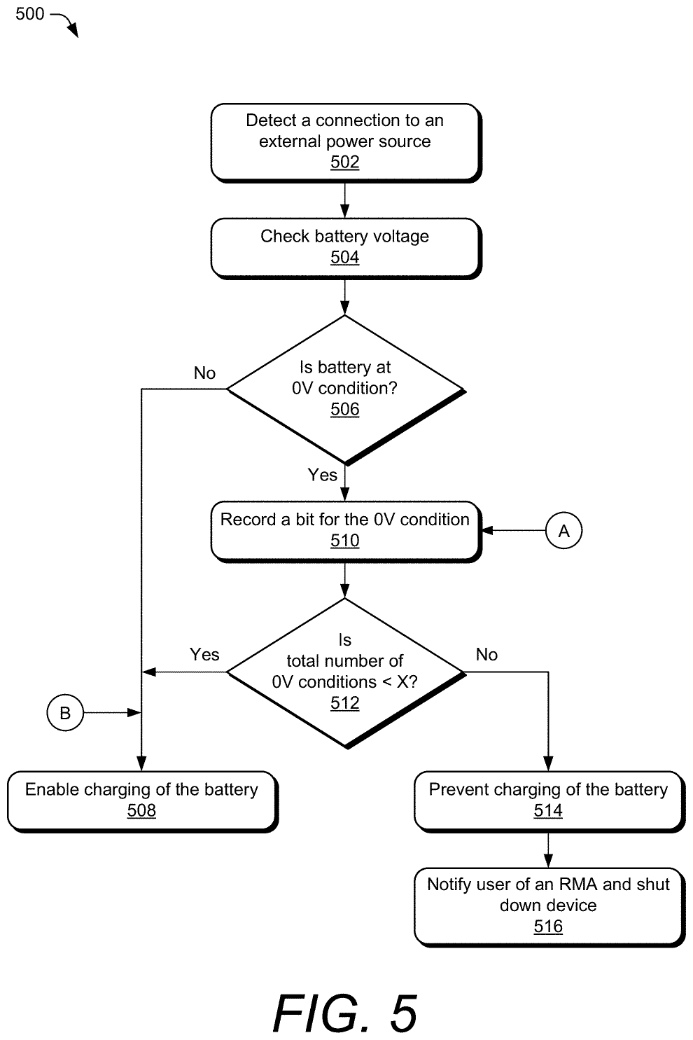

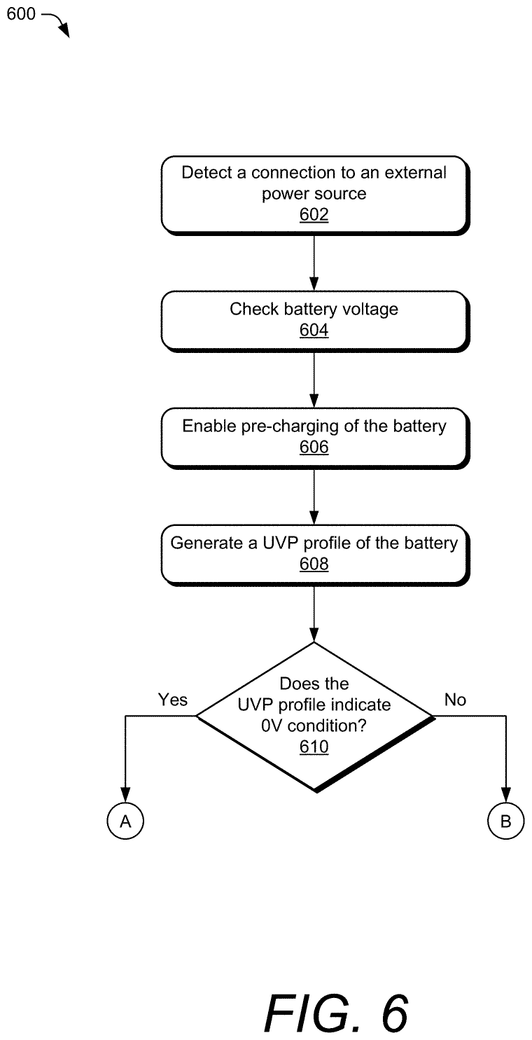

FIGS. 5 and 6 depict example methods 500 and 600 for battery zero-voltage detection. In particular, FIG. 5 depicts an example method for controlling battery charging of a battery in an electronic device. FIG. 6 depicts a method for detecting a zero-voltage condition of a battery in an electronic device. The methods 500 and 600 can be performed by the electronic device 102, which uses the battery-manager module 112 to implement the described techniques. The methods 500 and 600 collectively provide enhanced reliability and sustainability for the battery 104 and the electronic device 102. The method 600 is supplemental to, and is optionally performed in conjunction with, the method 500.

The methods 500 and 600 are shown as a set of blocks that specify operations performed but are not necessarily limited to the order or combinations shown for performing the operations by the respective blocks. Further, any of one or more of the operations may be repeated, combined, reorganized, or linked to provide a wide array of additional and/or alternate methods. In portions of the following discussion, reference may be made to the example implementation 100 of FIG. 1 or to entities or processes as detailed in FIGS. 2-4, reference to which is made for example only. The techniques are not limited to performance by one entity or multiple entities operating on one device.

At 502, a connection to an external power source is detected. For example, the charger IC 108 detects an electrical connection to the external power source 106 for initiating a charging sequence and responsively causes a delay to occur prior to enabling charging of the battery 104.

At 504, a battery voltage is checked during the delay. For example, the charger IC 108 checks the battery voltage of the battery 104 of the electronic device 102. Using the cell-sense lines 320 and 324 in the circuitry 300 in FIG. 3 to bypass the power path to the battery 104, the charger IC 108 senses the battery voltage of the battery 104 without driving current to the battery 104.

At 506, the battery-manager module 112 determines if the battery voltage indicates a 0V condition. For example, if the battery voltage is detected to be less than a threshold voltage (e.g., 1.5V, 1.25V, 1.0V, 0.5V, 0.25V), then the 0V condition 116 has occurred. In aspects, the battery-manager module 112 may check the comparator circuit 110 to detect if the comparator circuit 110 has been triggered by the battery voltage dropping below the trigger point, which may be set to approximately 1V (e.g., 1.5V, 1.25V, 1V, 0.5V, 0.25V).

If the battery voltage does not indicate the occurrence of the 0V condition 116 (“NO” at 506), then at 508, charging of the battery is enabled. For example, if the battery voltage is sensed to be greater than approximately 1V, then the 0V condition 116 has not occurred and the battery 104 may therefore be charged. In another example, if the comparator circuit 110 has not been triggered, then the 0V condition 116 has not occurred and the battery 104 may be charged. It may be likely that the battery 104 experienced the UVP condition 114 and not the 0V condition 116 if the battery voltage is greater than approximately 1V but less than approximately 3V.

If the battery voltage indicates the 0V condition 116 (“YES” at 506), then at 510, a bit is recorded for the 0V condition 116. For example, if the battery voltage is sensed to be less than approximately 1V or if the comparator circuit 110 has been triggered, then the 0V condition 116 has occurred. Responsively, the battery-manager module 112 can set a bit to one. In an example, the battery-manager module 112 can increment a counter (e.g., stored value) by one to track the number of occurrences of the 0V condition 116 for the battery 104. The bit and/or the counter may be stored in persistent memory on the system side. In aspects, the counter may be the bit stored in permanent storage in the memory.

At 512, the battery-manager module 112 determines if a total number of occurrences of the 0V condition for the battery has exceeded a threshold number of occurrences X. For example, the battery-manager module 112 compares the bit or the stored value to the threshold number of occurrences X In aspects, the threshold number of occurrences X is a positive integer (e.g., one, two, three, four). Because the threshold number of occurrences X is a positive integer, the battery 104 is permitted to experience at least one 0V condition without becoming non-recoverable (e.g., “bricked”). Some devices may be permitted only one 0V condition based on the cell chemistry of the battery 104 while some other batteries may be permitted to experience two, three, or more 0V conditions before significant damage occurs to the batteries, thereby extending the usable life cycle of the batteries.

If the total number of 0V conditions is less than the threshold number of occurrences X (“YES” at 512), then the method 500 proceeds to 508 to enable charging of the battery 104. If, however, the total number of 0V conditions is greater than (or equal to) the threshold number of occurrences X (“NO” at 512), then at 514, charging of the battery is prevented. For example, the battery-manager module 112 determines that the battery 104 has experienced the 0V condition too many times and prevents further use of the battery 104 by preventing charging of the battery 104. Too many 0V conditions may cause permanent damage to the battery 104, making further use of the battery 104 potentially hazardous and unsafe.

At 516, the user is notified of a return merchandise authorization (RMA) and the device is shut down (e.g., the battery 104 is disabled). For example, using line power from the external power source 106, a notification may be presented to the user via the display device 218 of the electronic device 102, which informs the user that the battery 104 is no longer usable and the user should return the electronic device 102. In another example, the notification may be transmitted to another device associated with the user. In aspects, the notification may be an audible sound, an audio recording, a text message, and so forth. To prevent potential use of the battery 104, the electronic device 102 may then be shut down.

FIG. 6 depicts a method 600 of detecting a zero-voltage condition of a battery in an electronic device. The method 600 may be performed by the electronic device 102, using the charger IC 108, the comparator circuit 110, and the battery-manager module 112.

At 602, a connection to an external power source is detected. For example, the charger IC 108 detects an electrical connection to the external power source 106 and responsively causes a delay to occur prior to enabling charging of the battery 104.

At 604, a battery voltage is checked during the delay. For example, the charger IC 108 checks the battery voltage of the battery 104 of the electronic device 102. In some instances, the battery voltage may be measured as 0V even though the battery 104 may still have minimal charge (e.g., greater than 0V but less than 3V).

At 606, pre-charging of the battery is enabled. For example, the battery 104 may be charged with a low current (e.g., a charge rate of C/50 or less) to minimize or reduce potential damage to the battery 104.

At 608, a UVP profile of the battery is generated. For example, the battery-manager module 112 monitors the battery voltage during the pre-charging of the battery 104 and maps the battery voltage to generate a UVP profile (e.g., the UVP profile 406 in FIG. 4). Accordingly, the UVP profile is a voltage curve (e.g., the change in battery voltage with respect to time), based on an applied current, of a battery having a battery voltage of less than a threshold voltage defined by a UVP condition (e.g., <3V). In some cases, the battery may have a battery voltage that is at or near zero voltage. The UVP profile may be used to distinguish between the 0V condition 116 and the UVP condition 114, such as when the initial battery voltage measurement is unreliable. In aspects, one or more signature patterns in the UVP profile are evaluated to identify the likelihood of the UVP condition 114 versus the 0V condition 116. A signature pattern is a portion of the voltage curve showing a behavior of the voltage change that is indicative of a particular low-voltage state (e.g., the UVP condition 114 or the 0V condition 116) of the battery as the battery is charged. In FIG. 4, the signature pattern may be identified as the quick rises and drops of the voltage that represent the FET interaction (e.g., closing of the FETs 306) as the current is applied to the battery. In an example, one or more characteristics (e.g., timing) of the signature patterns are used to indicate whether the battery 104 is more likely in the 0V condition 116 or the UVP condition 114.

At 610, the battery-manager module 112 determines whether the UVP profile indicates the occurrence of the 0V condition. For example, when the pre-charge current is applied to the battery 104, the battery-manager module 112 analyzes the timing of the FET interaction (e.g., closure of the two series-connected body diodes 308).

If the FET interaction occurs relatively slowly (e.g., on the order of seconds), then the battery-manager module 112 determines that the 0V condition has occurred (“YES” at 610). Because the battery experienced the 0V condition 116, the method 600 proceeds to “A,” which leads to 510 in FIG. 5 to record a bit for the 0V condition 116 and further determine whether to enable or prevent charging of the battery 104 based on the number of occurrences of the 0V condition 116.

Returning to 610, if the FET interaction occurs relatively quickly (e.g., on the order of milliseconds), then the battery-manager module 112 may determine that the UVP profile 406 indicates the UVP condition 114 and not the 0V condition 116 (“NO” at 610). Because the battery 104 has not experienced the 0V condition 116, the method 600 proceeds to “B,” which leads to 508 in FIG. 5 to enable charging of the battery 104.

Some examples are described below:

A method for detecting a zero-voltage condition of a battery in an electronic device, the method comprising: measuring a battery voltage of the battery in response to a detection of an electrical connection to an external power source for initiating a charging sequence; detecting a zero-voltage condition based on the battery voltage being below a first threshold voltage; incrementing an integer counter by one count in response to the detection of the zero-voltage condition; comparing the integer counter to a second threshold; and charging the battery when the integer counter is below the second threshold effective to permit the battery to experience at least one occurrence of the zero-voltage condition.

The incrementing the integer counter may include accessing a memory of the electronic device to increase the integer counter by one count; and the integer counter may represent a total number of occurrences of the zero-voltage condition for the battery over a life of the battery.

The method may further comprise determining that the total number of occurrences of the zero-voltage condition for the battery is less than or equal to the second threshold.

The second threshold may be one, effective to permit the battery to experience the zero-voltage condition one time.

The method may further comprise preventing the charging of the battery when the integer counter is greater than the second threshold.

The method may further comprise providing a return-merchandizing-authorization notification to a user of the electronic device.

The providing the return-merchandizing-authorization notification may include presenting a displayable notification via a display device of the electronic device.

The providing the return-merchandizing-authorization notification may include providing an audible message to the user.

The method may further comprise: subsequent to providing the return-merchandizing-authorization notification, shutting down the electronic device to prevent further use of the battery.

The method may further comprise, in response to the detection of the electrical connection to the external power source and prior to measuring the battery voltage, causing a delay to occur before initiating the charging sequence.

The measuring the battery voltage may include using sensing circuitry that bypasses a power path to the battery to sense the battery voltage without driving current to the battery.

The incrementing the integer counter by one count may include setting a bit in the memory of the electronic device to one.

The method may further comprise using a comparator circuit to trigger the zero-voltage condition when the battery voltage of the battery drops below a trigger point of the comparator circuit, the trigger point set to one volt.

An electronic device comprising: a battery; a default charger integrated circuit configured to cause a charging delay that delays battery charging when the electronic device is electrically connected to an external power source; a comparator circuit powered by battery voltage of the battery, the comparator circuit having a trigger point that triggers when a battery voltage of the battery decreases to less than the trigger point; and a system having a processor and memory, the system configured to implement a battery-manager module configured to perform the method disclosed above.

The electronic device may further comprise cell-sense lines directed from the battery to the system and configured to bypass a field-effect transistor and a power path to the battery.

A method for detecting a zero-voltage condition of a battery in an electronic device, the method comprising: pre-charging the battery using an electrical connection to an external power source, the battery having triggered an undervoltage-protection condition based on a battery voltage of the battery decreasing below a first threshold voltage; generating an undervoltage-protection profile of the battery voltage during the pre-charging of the battery based on interactions between protection integrated circuits, the battery, and a system of the electronic device; mapping the undervoltage-protection profile to create a signature pattern; and using one or more characteristics of the signature pattern to distinguish between the undervoltage-protection condition of the battery and the zero-voltage condition of the battery, the zero-voltage condition defined by a second threshold voltage that is less than the first threshold voltage of the undervoltage-protection condition.

The method may further comprise: based on a determination that the battery is in the zero-voltage condition, accessing a memory of the electronic device to increase a counter by one; and identifying a total number of occurrences of the zero-voltage condition for the battery over a life of the battery based on the counter.

The method may further comprise: determining that the total number of occurrences of the zero-voltage condition for the battery is less than or equal to a threshold number; and in response to the determining, enabling charging of the battery.

The threshold number may be one, effective to permit the battery to experience the zero-voltage condition one time.

The method may further comprise: determining that the counter exceeds the threshold number; and in response to determining that the counter exceeds the threshold number, preventing charging of the battery.

The method may further comprise providing a return-merchandizing-authorization notification to a user of the electronic device.

The providing the return-merchandizing-authorization notification may include presenting a displayable notification via a display device of the electronic device.

The providing the return-merchandizing-authorization notification may include providing an audible message to the user.

The method may further comprise, subsequent to providing the return-merchandizing-authorization notification, shutting down the electronic device to prevent further use of the battery.

The threshold number may be a positive integer.

The one or more characteristics may include a timing of a field-effect-transistor, FET, interaction during the pre-charging of the battery, the FET interaction may include a closure of at least two series-connected body diodes.

The method may further comprise determining, based on the timing of the FET interaction being less than 50 milliseconds, that the battery is in the undervoltage-protection condition.

The method may further comprise determining, based on the timing of the FET interaction being from 1 to 20 seconds, that the battery is in the zero-voltage condition.

The method may further comprise using a comparator circuit to trigger the zero-voltage condition when the battery voltage drops below a trigger point of the comparator circuit, the trigger point set to one volt.

An electronic device comprising: a battery; sensing circuitry having at least two protection integrated circuits each having a pair of field-effect transistors coupled with two body diodes to form a bidirectional power switch usable during a pre-charge of the battery to generate an undervoltage-protection profile for distinguishing between an undervoltage condition of the battery and a zero-voltage condition of the battery; and a system having a processor and memory and configured to implement a battery-manager module configured to perform the method disclosed above.

A computer-readable medium comprising instructions which, when executed by one or more processors, cause the one or more processors to carry out the method disclosed above.

An electronic device comprises: a battery; a system having a processor and memory, a default charger integrated circuit configured to cause a charging delay that delays battery charging when the electronic device is electrically connected to an external power source; a comparator circuit powered by battery voltage of the battery and configured to: have a trigger point set to approximately one volt; and in response to the trigger point being triggered by the battery voltage decreasing to less than the trigger point, increase a counter in the memory of the system; and cell-sense lines directed from the battery to the system and configured to bypass a field-effect transistor and a power path to the battery.

The zero-voltage condition may be a battery voltage of less than one volt. In some implementations. In addition or as an alternative, in some of these implementations, the undervoltage-protection condition may be a battery voltage between one volt and three volts.

The cell-sense lines may be connected to a positive terminal and a negative terminal of the battery with a high-resistance path.

The counter may be a bit stored in permanent storage in the memory.

The processor may be configured to execute instructions in the memory to: during pre-charging of the battery, determine a current going into the battery and timing to achieve an opening or closing of the MOSFET; create a profile from readings of the current battery and the timing; and indicate, based on the profile, that the battery has experienced the zero-voltage condition.

### CONCLUSION

Although aspects of battery zero-voltage detection methodologies and applications thereof have been described in language specific to features and/or methods, the subject of the appended claims is not necessarily limited to the specific features or methods described. Rather, the specific features and methods are disclosed as example implementations of the techniques for battery zero-voltage detection methodologies and applications thereof, and other equivalent features and methods are intended to be within the scope of the appended claims. Further, various different aspects are described, and it is to be appreciated that each described aspect can be implemented independently or in connection with one or more other described aspects.

1. A method for controlling charging events of a battery in an electronic device, the method comprising:
measuring a battery voltage of the battery in response to a detection of an electrical connection to an external power source for initiating a charging sequence;
detecting a zero-voltage condition based on the battery voltage being below a first threshold voltage;
incrementing an integer counter by one count in response to the detection of the zero-voltage condition;
comparing the integer counter to a second threshold; and
charging the battery when the integer counter is below the second threshold effective to permit the battery to experience at least one occurrence of the zero-voltage condition.

2. The method of claim 1, wherein:
incrementing the integer counter includes accessing a memory of the electronic device to increase the integer counter by one count; and
the integer counter represents a total number of occurrences of the zero-voltage condition for the battery over a life of the battery.

3. The method of claim 2, further comprising determining that the total number of occurrences of the zero-voltage condition for the battery is less than or equal to the second threshold.

4. The method of any one of claim 1, wherein the second threshold is one, effective to permit the battery to experience the zero-voltage condition one time.

5. The method of claim 1, further comprising preventing the charging of the battery when the integer counter is greater than the second threshold.

6. The method of claim 5, further comprising providing a return-merchandizing-authorization notification to a user of the electronic device.

7. The method of claim 6, wherein providing the return-merchandizing-authorization notification includes presenting a displayable notification via a display device of the electronic device.

8. The method of claim 6, wherein providing the return-merchandizing-authorization notification includes providing an audible message to the user.

9. The method of any one of claim 5, further comprising:
subsequent to providing the return-merchandizing-authorization notification, shutting down the electronic device to prevent further use of the battery.

10. The method of any one of claim 1, further comprising, in response to the detection of the electrical connection to the external power source and prior to measuring the battery voltage, causing a delay to occur before initiating the charging sequence.

11. The method of any one of claim 1, wherein measuring the battery voltage includes using sensing circuitry that bypasses a power path to the battery to sense the battery voltage without driving current to the battery.

12. The method of any one of claim 1, wherein incrementing the integer counter by one count includes setting a bit in the memory of the electronic device to one.

13. The method of any one of claim 1, further comprising using a comparator circuit to trigger the zero-voltage condition when the battery voltage of the battery drops below a trigger point of the comparator circuit, the trigger point set to one volt.

14. An electronic device comprising:
a battery;
a default charger integrated circuit configured to cause a charging delay that delays battery charging when the electronic device is electrically connected to an external power source;
a comparator circuit powered by battery voltage of the battery, the comparator circuit having a trigger point that triggers when a battery voltage of the battery decreases to less than the trigger point; and
a system having a processor and memory, the system configured to implement a battery-manager module configured to:
measure a battery voltage of the battery in response to a detection of an electrical connection to an external power source for initiating a charging sequence;
detect a zero-voltage condition based on the battery voltage being below the trigger point of the comparator circuit;
increment an integer counter by one count in response to the detection of the zero-voltage condition;
compare the integer counter to a threshold value; and
charge the battery when the integer counter is below the threshold value effective to permit the battery to experience at least one occurrence of the zero-voltage condition.

15. The electronic device of claim 14, further comprising cell-sense lines directed from the battery to the system and configured to bypass a field-effect transistor and a power path to the battery.

16. The electronic device of claim 15, wherein the cell-sense lines include a first cell-sense line that:
has a first high resistor in-line; and
directly connects to positive cell voltage of the battery.

17. The electronic device of claim 16, wherein the cell-sense lines include a second cell-sense line that:
has a second high resistor in-line; and
directly connects to negative cell voltage of the battery.

18. The electronic device of claim 14, wherein the integer counter is incremented by one count based on a bit being set in the memory of the electronic device to one.

19. The electronic device of claim 14, further comprising one or more bidirectional power switches and one or more protection integrated circuits.

20. The electronic device of claim 14, further comprising two protection integrated circuits (PICs) connected in series, each PIC having a pair of field effect transistors, each pair of field effect transistors arranged with two body diodes that are back to back.
